(19) United States
(12) Patent Application Publication
(10) Pub. No.: US 2026/0212172 A1
(43) Pub. Date: Jul. 23, 2026

(54) NEURAL NETWORK APPARATUS

(71) Applicant: SAMSUNG ELECTRONIC CO., LTD., Suwon-si (KR)

(72) Inventors: Minsik PARK, Suwon-si (KR); Seijoon KIM, Suwon-si (KR); Minyoung MUN, Suwon-si (KR)

(73) Assignee: SAMSUNG ELECTRONIC CO., LTD., Suwon-si (KR)

(21) Appl. No.: 19/450,099

(22) Filed: Jan. 15, 2026

(30) Foreign Application Priority Data
Jan. 17, 2025 (KR) 10-2025-0007547

(51) Int. Cl. G06N 3/063; G06F 7/544

(52) U.S. Cl. CPC G06N 3/063; G06F 7/5443

(57) ABSTRACT

A neural network apparatus according to an embodiment includes a plurality of bit lines extending in parallel in a first direction, a plurality of word lines extending in parallel in a second direction intersecting the first direction, a plurality of source lines extending in parallel with the plurality of bit lines in the first direction and arranged in parallel with each other in the second direction, and a plurality of bit cells each arranged in a region where the plurality of bit lines and the plurality of word lines intersect, wherein each of the bit cells includes a plurality of nonvolatile memories connected in parallel with each other, a first switch connected between one end of the plurality of volatile memories and one of the plurality of source lines, and second switches arranged between one of the bit lines and each other end of the plurality of volatile memories.

### CROSS-REFERENCE TO RELATED APPLICATION

This application is based on and claims priority under 35 U.S.C. § 119 to Korean Patent Application No. 10-2025-0007547, filed on Jan. 17, 2025, in the Korean Intellectual Property Office, the disclosure of which is incorporated by reference herein in its entirety.

### BACKGROUND

### 1. Field

The disclosure relates to a neural network apparatus.

### 2. Description of the Related Art

Recently, there has been an increased interest in neuromorphic processors that perform neural network operations. For example, research is being conducted to implement a neuromorphic processor that includes a neuron circuit and a synapse circuit. Such a neuromorphic processor may be used as a neural network apparatus to drive various neural networks such as a CNN, an RNN, a feedforward neural network (FNN), etc., and may be utilized in fields including data classification or image recognition.

Related art neural network apparatuses have attempted to supplement and overcome related problems by designing preconditioners or peripheral circuits to overcome accuracy degradation due to analog noise in analog circuits and systems. In particular, the preprocessor refers to a technology or circuit used to improve the performance of a signal or system or to increase the efficiency of a subsequent processing operation. For example, the preprocessor may include a signal-controlling circuit such as a signal amplifier, a filter, and a voltage regulator, a biasing circuit, an impedance matching circuit, a level shifter, an offset compensator, and a compensation circuit for correcting quantization errors and nonlinearity errors.

According to a related art a preprocessing method, in order to resolve the residual error, which is the difference between a desired precision and a realized precision in an analog crossbar, a continuous calculation method that is relatively easy to implement while maintaining the desired high accuracy for writing accuracy and device variability has been proposed using multiple analog crossbars. Compared to a related art bit-slicing method, the continuous calculation method has a relatively simple circuit configuration and may reduce the use of an analog-to-digital converter, thus providing an advantage in terms of area and power consumption.

### SUMMARY

In a case in which a preprocessor or peripheral circuit is used in a circuit and system for related art analog operations, it is possible to solve a problem of low accuracy due to analog noise, but there are trade-offs such as additional power consumption and increased circuit complexity.

In addition, a method of using multiple analog crossbars to solve residual errors occurring in an analog crossbar that has been recently proposed may also have a problem of increasing a number of analog crossbar layers in order to implement high accuracy.

Provided is a neural network apparatus that may reduce residual errors without excessive cost increase due to additional circuits and algorithms through a simple structural change that includes multiple nonvolatile memories in a unit bit cell structure.

The technical problems to be achieved are not limited to the above technical problems, and other technical problems may be inferred from the following embodiments.

Additional aspects will be set forth in part in the description which follows and, in part, will be apparent from the description, or may be learned by practice of the presented embodiments of the disclosure.

According to an aspect of the disclosure, there is provided a neural network apparatus including: a plurality of bit lines extending in a first direction, a plurality of word lines extending in a second direction intersecting with the first direction, a plurality of source lines extending in parallel with the plurality of bit lines in the first direction and a plurality of bit cells, each of the plurality of bit cells arranged in a region where a respective one of the plurality of bit lines and a respective one of the plurality of word lines intersect, wherein each of the plurality of bit cells includes: a plurality of nonvolatile memories; a first switch connected between a first end of each of the plurality of nonvolatile memories and one of the plurality of source lines; and a plurality of second switches, each of the plurality of second switches connected to one of the plurality of bit lines and a second end of a respective one of the plurality of nonvolatile memories.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram for explaining the architecture of a neural network according to an embodiment;

FIG. 2 is a diagram for explaining operations performed in a neural network according to an embodiment;

FIG. 3 is a diagram showing an in-memory computing circuit according to an embodiment;

FIG. 4 is a diagram for explaining a basic structure of a bit cell array according to a related art;

FIG. 5 is a diagram for explaining a basic structure of a bit cell array according to an embodiment;

FIG. 6 is a diagram showing an enlarged view of the bit cell of FIG. 5;

FIG. 7 is a diagram showing an enlarged view of the column circuit of FIG. 5;

FIG. 8A is a flowchart for explaining a write circuit of a neural network apparatus;

FIG. 8B is a flowchart for explaining an operation (or read) circuit of a neural network apparatus;

FIG. 9A is a diagram showing a modification to the bit cell shown in FIG. 6 according to an embodiment;

FIG. 9B is a diagram showing a modification to the column circuit shown in FIG. 7 according to an embodiment; and

FIG. 10 is a block diagram showing the configuration of an electronic system according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Terminologies used in the present embodiment are selected as commonly used by those of ordinary skill in the art in consideration of functions of the current embodiment, but may vary according to the technical intention, precedents, or a disclosure of new technology. Also, in particular cases, some terms are arbitrarily selected, and in this case, the meanings of the terms will be described in detail at corresponding parts of the specification. Accordingly, the terms used in the present embodiments should be defined not by simply the names of the terms but based on the meaning and contents of the whole specification.

In the descriptions of the embodiments, it will be understood that, when an element is referred to as being “connected” to another element, it may include electrically connected when the element is directly connected to the other element and when the element is indirectly connected to the other element by intervening a constituent element. Also, it should be understood that, when a part “comprises” or “includes” a constituent element in the specification, unless otherwise defined, it is not excluding other elements but may further include other elements.

It will be further understood that the term “comprises” or “includes” should not be construed as necessarily including various constituent elements and various operations described in the specification and also should not be construed that portions of the constituent elements or operations of the various constituent elements and various operations may not be included or additional constituent elements and operations may further be included.

It will be understood that, although the terms ‘first’, ‘second’, etc. may be used herein to describe various constituent elements, these constituent elements should not be limited by these terms These terms are only used to distinguish one constituent element from another.

The descriptions of the embodiments should not be interpreted as limiting the scope of right, and embodiments that are readily inferred from the detailed descriptions and embodiments by those of ordinary skill in the art will be construed as being included in the inventive concept. Reference will now be made in detail to embodiments, examples of which are illustrated in the accompanying drawings.

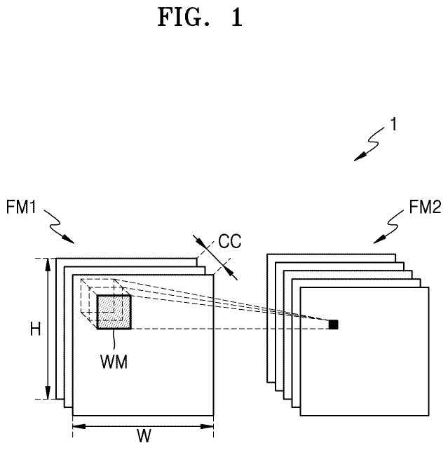

FIG. 1 is a diagram for explaining the architecture of a neural network 1 according to an embodiment.

Referring to FIG. 1, the neural network 1 may be expressed as a mathematical model using nodes and edges. The neural network 1 may be an architecture of a deep neural network (DNN) or an n-layer neural network. The DNN or n-layer neural network may include, but the disclosure is not limited to, a convolutional neural network (CNN), a recurrent neural network (RNN), a deep belief network, a restricted Boltzmann machine, etc. For example, the neural network 1 may be implemented as a CNN, but the disclosure is not limited thereto. The neural network 1 of FIG. 1 may correspond to some layers of a CNN. Therefore, the neural network 1 may correspond to a convolutional layer, a pooling layer, a fully connected layer, etc. of the CNN. However, for convenience, in the following description, the neural network 1 corresponds to a convolutional layer of the CNN, but the disclosure is not limited thereto.

In the convolutional layer, a first feature map FM1 may correspond to an input feature map, and a second feature map FM2 may correspond to an output feature map. A feature map may denote a data set in which various features of input data are expressed. The first and second feature maps FM1 and FM2 may be high-dimensional matrices of two or more dimensions, and each has its own activation parameters. In an example case in which the first and second feature maps FM1 and FM2 correspond to, for example, three-dimensional feature maps, the first and second feature maps FM1 and FM2 have a width W (or referred to as a column), a height H (or referred to as a row), and a depth CC. For example, the depth CC may correspond to the number of channels.

In the convolution layer, a convolution operation may be performed on the FM1 and a weight map WM, and as a result, the FM2 may be generated. The weight map WM may filter the first feature map FM1 and is referred to as a weight filter or a weight kernel. In an example, the depth of the weight map WM, e.g., the number of channels, is equal to the depth of the first feature map FM1, e.g., the number of channels. The weight map WM is shifted in a manner of traversing the first feature map FM1 as a sliding window. During each shift, each of the weights included in the weight map WM may be multiplied and added to all feature values in an area overlapping with the first feature map FM1. As the first feature map FM1 and the weight map WM are convolved, one channel of the second feature map FM2 may be generated.

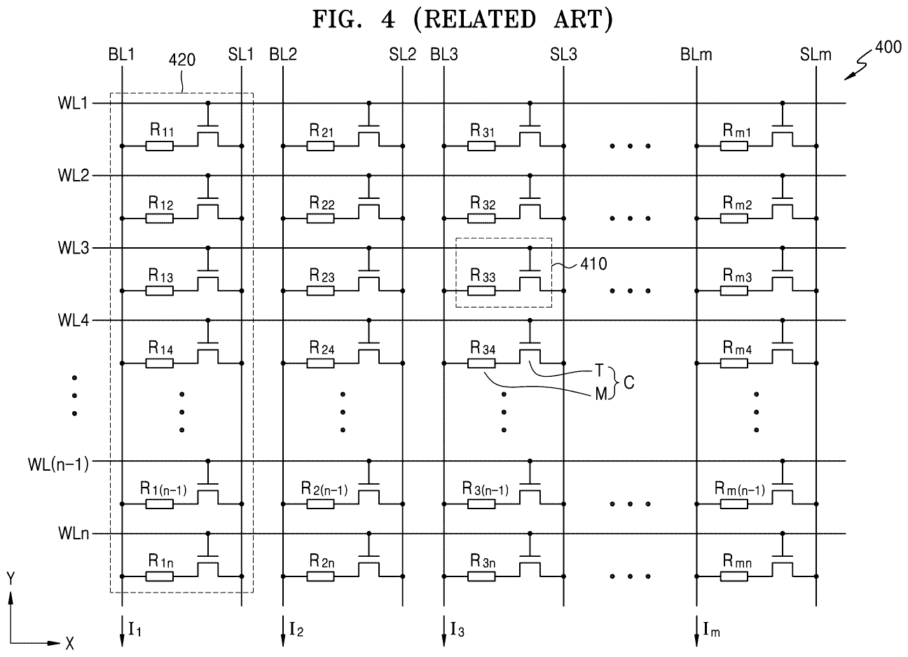

In FIGS. 4 to 9 described below, a voltage transmitted through word lines may be a bit value corresponding to an input activation included in the input feature map. A resistance value or data value (0 or 1) of a variable resistance device may be a bit value corresponding to the weight map WM.

According to an embodiment, neural network generation devices may perform neural network operations using bit values corresponding to input activations and bit values corresponding to weight maps WMs. The neural network operation may be an operation on a Binary Neural Network BNN.

According to an embodiment, one weight map WM is shown in FIG. 1. However, the disclosure is not limited to, and as such, according to another embodiment, multiple weight maps may be convolved with the first feature map FM1 to generate a plurality of channels of the second feature map FM2. The second feature map FM2 of the convolution layer may be an input feature map of the next layer. For example, the second feature map FM2 may be an input feature map of a pooling layer. However, the disclosure is not limited thereto.

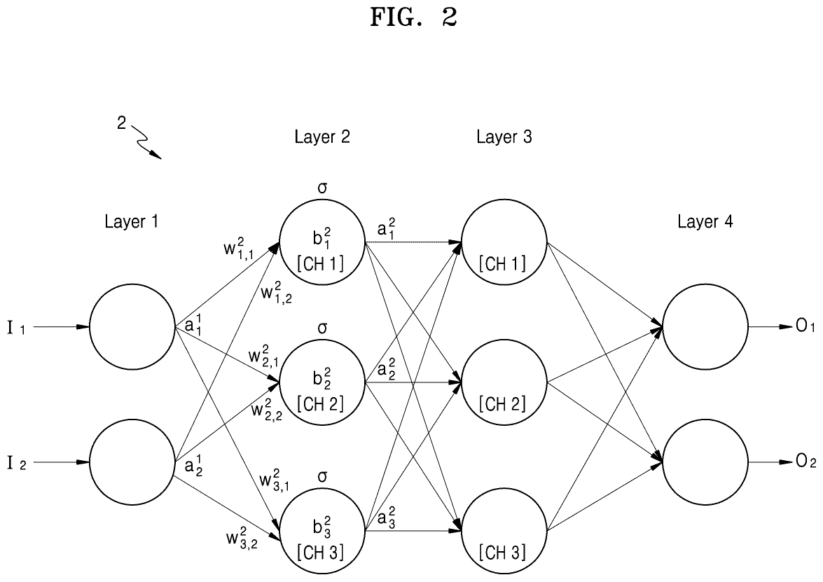

FIG. 2 is a diagram for explaining an operation performed in a neural network 2 according to an embodiment.

Referring to FIG. 2, the neural network 2 has a structure including an input layer, hidden layers, and an output layer, and may perform operations based on received input data (e.g., I₁ and I₂) and may generate output data (e.g., O₁ and O₂) based on the results of the operations.

The neural network 2 may be a DNN including two or more hidden layers or an n-layer neural network as described above. For example, as illustrated in FIG. 2, the neural network 2 may be a DNN including an input layer (Layer 1), two hidden layers (Layer 2 and Layer 3), and an output layer (Layer 4). In an example case in which the neural network 2 is implemented with a DNN architecture, the neural network 2 includes more layers capable of processing valid information, and thus, the neural network 2 may process more complex data sets than a neural network having a single layer. According to an embodiment, the neural network 2 may include four layers as shown in FIG. 2, but this is only an example, and as such, according to another embodiment, the neural network 2 may include more or less layers, or more or less channels. For example, the neural network 2 may include layers of various structures different from those illustrated in FIG. 2.

Each of the layers included in the neural network 2 may include multiple channels. The channels may correspond to neurons, processing elements (PEs), units, or multiple artificial nodes known as similar to the above terms. For example, as illustrated in FIG. 2, Layer 1 may include two channels (nodes), and Layer 2 and Layer 3 may each include three channels. However, this is an example, and each of the layers included in the neural network 2 may include a variety of numbers of channels (nodes).

The channels included in each layer of the neural network 2 may be connected to each other to process data. For example, one channel may receive data from other channels, perform calculations, and output the calculation results to other channels.

The input and output of each channel may be referred to as input activation and output activation, respectively. That is, an activation may be an output of one channel and a parameter corresponding to an input of channels included in the next layer. Each channel may determine its own activation based on the activations and weights received from the channels included in the previous layer. The weight is a parameter used to calculate the output activation in each channel and may be a value assigned to a connection relationship between the channels.

Each of the channels may be processed by a computational unit or PE that receives input and outputs an output activation, and the input-output of each channel may be mapped. In an example case in which σ is an activation function,

$${w}_{jk}^{i}$$

is a weight from the k^{th} channel included in an (i−1)^{th} layer to the j^{th} channel included in an i^{th} layer,

$${b}_{j}^{i}$$

is a bias of a j^{th} channel included in the i^{th} layer, and

$${a}_{j}^{i}$$

is an activation of the j^{th} channel of the i^{th} layer, the activation

$${a}_{j}^{i}$$

may be calculated using the following equation (1).

$${a}_{j}^{i} = σ ( {\sum }_{k} ( {w}_{jk}^{i} \times {a}_{k}^{i - 1} ) + {b}_{j}^{i} ) \qquad ( 1 )$$

As shown in FIG. 2, the activation of the first channel CH1 of the second layer 2 may be expressed as

$${a}_{1}^{2} .$$

In addition,

$${a}_{1}^{2}$$

may have a value of

$${a}_{1}^{2} = σ ( {w}_{1 , 1}^{2} \times {a}_{1}^{1} + {w}_{1 , 2}^{2} \times {a}_{2}^{1} + {b}_{1}^{2} )$$

according to equation (1). The activation function o may be a Rectified Linear Unit (ReLU), but the disclosure is not limited thereto. For example, the activation function o may be a Sigmoid, a Hyperbolic Tangent (tanh), a Maxout, etc.

As explained above, in the neural network 2, numerous data sets are exchanged between multiple interconnected channels and undergo a computational process while passing through the layers. In this computational process, numerous Multiply-accumulate (MAC) operations are performed, and numerous memory access operations must be performed together to load the activation and weight, which are operands of the MAC operation, at an appropriate time.

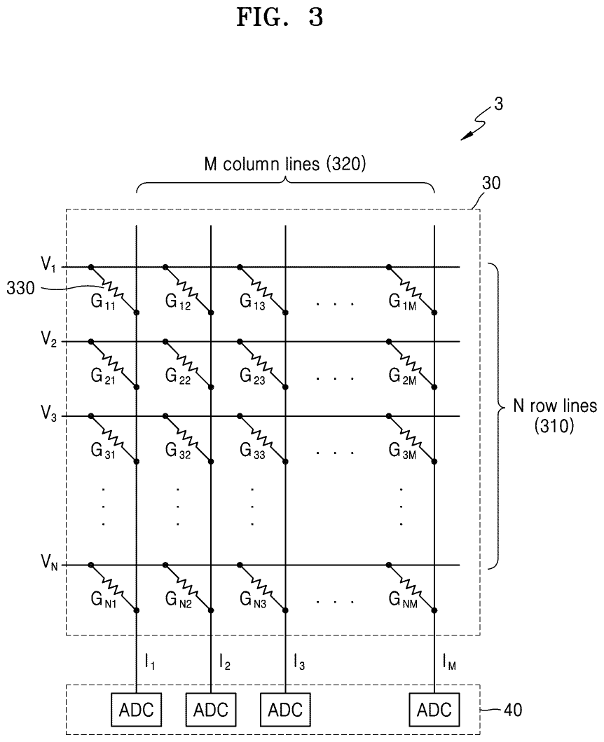

In a related art digital computer, a Von Neumann architecture maybe used, in which, the computational unit and memory are separated and a common data bus is included for data transmission between the two separated blocks. In such a case, in the process of implementing the neural network 2 in which data movement and computation are continuously repeated, a lot of time is required for data transmission and excessive power consumption may occur. To overcome this problem, an in-memory computing circuit may be provided as an architecture that integrates the memory and computational unit for performing MAC operations into one. An in-memory computing circuit will be described in more detail below with reference to FIG. 3.

FIG. 3 is a diagram showing an in-memory computing circuit 3 according to one or more embodiments.

Referring to FIG. 3, the in-memory computing circuit 3 may include an analog crossbar array 30 and an Analog to Digital Converter (ADC) 40. However, only components related to explaining one or more of the embodiments are illustrated in the in-memory computing circuit 3 illustrated in FIG. 3. Therefore, it is obvious to those skilled in the art that the in-memory computing circuit 3 may further include other general components in addition to the components illustrated in FIG. 3.

The analog crossbar array 30 may include a plurality of row lines 310, a plurality of column lines 320, and a plurality of bit cells 330. The plurality of row lines 310 may be used to receive input data. In an example case in which the plurality of row lines 310 are N row lines (N is any natural number), voltages V₁, V₂, . . . , V_{N} corresponding to input activations may be applied to the N row lines. The plurality of column lines 320 may intersect with the plurality of row lines 310. In an example case in which the plurality of column lines 320 are M column lines (M is any natural number), the plurality of column lines 320 and the plurality of row lines 310 may intersect at N x M intersections.

The plurality of bit cells 330 may be arranged at the intersections of the plurality of row lines 310 and the plurality of column lines 320. Each of the plurality of bit cells 330 may be implemented as a nonvolatile memory including, but not limited to, Phase change Random Access Memory (PRAM), Resistive Random Access Memory (RRAM), and Magnetic Random Access Memory (MRAM) corresponding to a current domain to store weights or may be implemented as a nonvolatile memory among Ferroelectric Random Access Memory (FeRAM), eFlash, and FeFET corresponding to a charge domain.

In an embodiment, the bit cell 330 may include a phase-change material. In the phase-change material, a crystal state may change depending on the amount of current. The phase-change material may include various types of materials, such as GaSb, InSb, InSe, Sb₂Te₃, and GeTe, which are compounds of two elements, GeSbTe, GaSeTe, InSbTe, SnSb₂Te₄, and InSbGe, which are compounds of three elements, and AgInSbTe, (GeSn) SbTe, GeSb (SeTe), and Te₈₁Ge₁₅Sb₂S₂, which are compounds of four elements. In another embodiment, the bit cell 330 may include, but is not limited to, perovskite compounds, transition metal oxides, magnetic materials, ferromagnetic materials, or antiferromagnetic materials. However, the resistive material included in the bit cell 330 is not limited to the materials described above.

In the example illustrated in FIG. 3, the plurality of bit cells 330 have conductances G₁₁, . . . , G_{NM} corresponding to weights, and in an example case in which a voltage corresponding to input activation is applied to each of the plurality of row lines 310, a current having a size of I=V×G may be output through each of the bit cells 330 according to Ohm's law. Because currents output from the bit cells 330 arranged along one column line are added together, a current sum I₁, . . . , I_{M} may be output along the plurality of column lines 320. The current sum I₁, . . . , I_{M} may correspond to the result of the MAC operation performed in an analog manner.

The ADC 40 may convert the result of the analog MAC operation (e.g., the current sum I₁, . . . , I_{M}) output from the analog crossbar array 30 into a digital signal. The result of the MAC operation converted into a digital signal may be output from the ADC 40 and used in the subsequent neural network operation process.

FIG. 4 is a diagram for explaining the basic structure of a bit cell array 400.

Referring to FIG. 4, a neural network apparatus having a parallel structure according to a related art is illustrated. For example, the bit cell array 400 of the neural network apparatus may include a plurality of bit cells C arranged in a matrix form. Each of the plurality of bit cells C may include a transistor T and a nonvolatile memory M. For example, the transistor T may be a MOS transistor or a bipolar transistor. Additionally, the bit cell array 400 may include a plurality of word lines WL, WL1, WL2, . . . , WLn, a plurality of bit lines BL, BL1, BL2, . . . , BLm, and a plurality of source lines SL, SL1, SL2 . . . , SLm. Each of the plurality of bit cells C may be electrically connected to the corresponding word line, bit line, and source line.

The plurality of word lines WL1, WL2, . . . , WLn may be arranged parallel to each other in a first direction (Y direction) and may extend in a second direction (X direction). The plurality of bit lines BL1, BL2, . . . , BLn may be arranged parallel to each other in the second direction while extending in the first direction. The plurality of source lines SL1, SL2, . . . , SLn may be arranged parallel to each other in the second direction while extending in the first direction in the same manner as the plurality of bit lines BL1, BL2, . . . , BLn. The plurality of word lines WL1, WL2, . . . , WLn may extend parallel to each other in the second direction intersecting the first direction and may be connected to the transistor T of each of the plurality of bit cells C.

The plurality of source lines SL1, SL2, . . . , SLn may be connected to sources or drains of the transistors T of the plurality of bit cells C, and the plurality of bit lines BL1, BL2, . . . , BLn may be connected to the sources or drains of the plurality of bit cells C. Here, the bit lines BL1, BL2, . . . , BLn may be considered to be connected to the drains or sources of the corresponding transistors T via the corresponding nonvolatile memory M.

Based on the connection relationship, in an example case in which one of the plurality of word lines WL1, WL2, . . . , WLn and one of the plurality of source lines SL1, SL2, . . . , SLn or one of the plurality of bit lines BL1, BL2, . . . , BLn is selected, one bit cell C may be selected. For example, in a case in which the third word line WL3 and the third source line SL3 or the third bit line BL3 are selected, a bit cell 410 including a variable resistance element R33 may be selected.

In an example case in which one word line and one bit line are selected, the corresponding source line may be automatically determined. Conversely, in an example case in which one word line and one source line are selected, the corresponding bit line may be automatically determined.

In the bit cell C, the transistor T may control the current supply to the nonvolatile memory M by being turned on or off according to a voltage of the word line.

In an example case in which a power voltage (e.g., VCC) is applied to the selected word line, a write voltage is applied to the selected bit line, and a ground voltage is applied to the selected source line, data ‘1’ is written to the selected nonvolatile memory M and the selected nonvolatile memory has a low resistance state, and in an example case in which the power voltage is applied to the selected word line, the ground voltage is applied to the selected bit line, and the write voltage is applied to the selected source line, data ‘0’ is written to the selected nonvolatile memory M and the selected nonvolatile memory has a high resistance state. In addition, in an example case in which the power voltage is applied to the selected word line, the read voltage is applied to the selected bit line, and the ground voltage is applied to the selected source line, data written in the selected nonvolatile memory M may be read out.

The bit cell array 400 may output a plurality of read currents I₁, I₂, I₃, . . . , Iₘ. In FIG. 4, the plurality of read currents I₁, I₂, I₃, . . . , Iₘ are illustrated as being output through the plurality of bit lines BL1, BL2, . . . , BLn, but the disclosure is not limited thereto, and the plurality of read currents I₁, I₂, I₃, . . . , Iₘ may also be output through the plurality of source lines SL1, SL2, . . . , SLn.

Referring again to FIG. 4, the bit cells C arranged in the first direction may be connected in parallel to form one column circuit 420. For example, the column circuit 420 indicated by a dashed line is configured by connecting n bit cells C in parallel in the first direction to the first source line SL1 and the first bit line BL1.

In an example case in which a neural network operation is performed, the bit cells C have resistors R₁₁, R₁₂, R₁₃, R₁₄, . . . , Rmn corresponding to the weights, and when a voltage corresponding to input activation is applied to each of the multiple word lines WL1, WL2, . . . , WLn, the transistor T is turned-on or turned-off to control the current supply to the nonvolatile memory M. When the transistor T is turned on, a current having a size of I=V/R may be output through each bit cell C according to Ohm's law. (V=voltage applied between the source line and the bit line and R=resistance value of the variable resistor element) The sum currents I₁, I₂, I₃, . . . , Iₘ may correspond to the results of neural network operations performed in an analog manner.

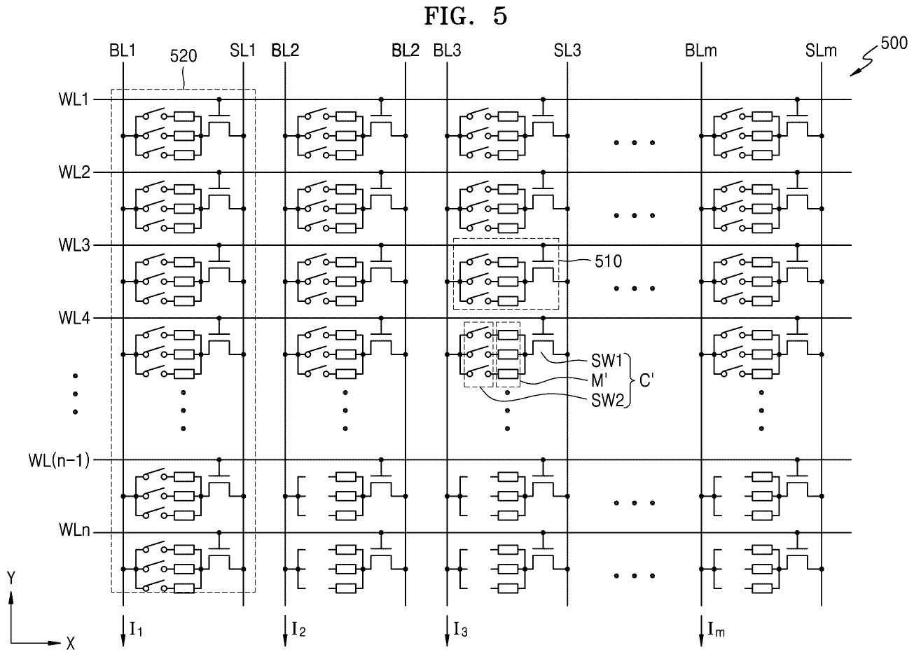

A unit bit cell C of an analog crossbar array may be configured of a transistor T that selects the corresponding bit cell C and a nonvolatile memory M that stores the weight used in the operation. For example, as illustrated in FIG. 4, the unit bit cell C may be configured of one transistor T and one nonvolatile memory M. In an example case in which the bit cell C is configured of only one nonvolatile memory M, and if the write performance of the nonvolatile memory M is very low, a residual error problem may occur, which may deteriorate the write precision of the neural network apparatus. Hereinafter, a method of improving the write precision of the neural network apparatus through a bit cell C′ including a plurality of nonvolatile memories M illustrated in FIG. 5 will be discussed.

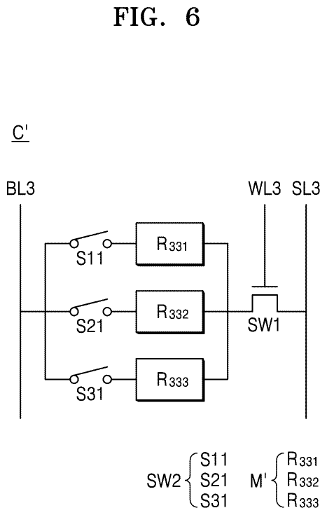

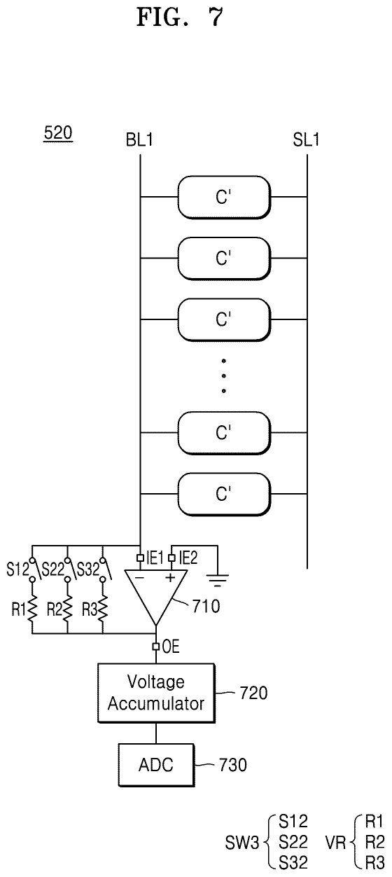

FIG. 5 is a diagram for explaining the basic structure of a bit cell array 500 according to an embodiment. FIG. 6 is an enlarged view of the bit cell of FIG. 5. FIG. 7 is an enlarged view of the column circuit of FIG. 5.

According to an embodiment, each of the bit cells C′ illustrated in FIG. 5 is different from the bit cell C illustrated in FIG. 4 in that the bit cells C′ illustrated in FIG. 5 include a plurality of nonvolatile memories M′ and a plurality of switches SW1 and SW2 and the bit cells C illustrated in FIG. 4 include one nonvolatile memory M and one transistor T, but the remaining configurations may be substantially the same. Hereinafter, overlapping descriptions will be omitted, and the differences in the structure of the bit cell C′ will be mainly described.

Referring to FIGS. 5 and 6, a neural network apparatus according to an embodiment is illustrated. For example, the bit cell array 500 of the neural network apparatus may include a plurality of bit cells C′ arranged in a matrix form. Each of the plurality of bit cells C′ may include a first switch SW1, second switches SW2, and nonvolatile memories M′. For example, the first switch SW1 and the second switches SW2 may be MOS transistors or bipolar transistors. However, the disclosure is not limited thereto, and as such, according to another embodiment, another type of switch may be provided.

In addition, the bit cell array 500 may include a plurality of word lines WL, WL1, WL2, . . . , WLn, a plurality of bit lines BL, BL1, BL2, . . . , BLm, and a plurality of source lines SL, SL1, SL2 . . . , SLm. Each of the plurality of bit cells C′ may be electrically connected to a corresponding word line, bit line, and source line.

The plurality of word lines WL1, WL2, . . . , WLn may be arranged in parallel with each other in the first direction (Y direction) and may extend in the second direction (X direction). The plurality of bit lines BL1, BL2, . . . , BLn may be arranged to extend parallel to each other in the first direction (Y direction) and parallel to each other in the second direction (X direction). The plurality of source lines SL1, SL2, . . . , SLn may be arranged in parallel with each other in the second direction (X direction) while extending in the first direction (Y direction) in the same manner as the plurality of bit lines BL1, BL2, . . . , BLn. The plurality of source lines SL1, SL2, . . . , SLn may be connected to the drains or sources of the first switches SW1 of the plurality of bit cells C′. The plurality of word lines WL1, WL2, . . . , WLn may extend in parallel in the second direction (X direction) intersecting the first direction (Y direction) and may be connected to the second switches SW2 of each of the plurality of bit cells C′.

Based on this connection relationship, one bit cell C′ may be selected by selecting one of the plurality of word lines WL1, WL2, . . . , WLn, and one of the plurality of source lines SL1, SL2, . . . , SLn or one of the plurality of bit lines BL1, BL2, . . . , BLn. In an example case in which the third word line WL3 and the third source line SL3 or the third bit line BL3 are selected, the bit cell 510 may be selected. Although FIG. 5 illustrates that each of the bit cells C′ in the bit cell array 500 is different from the bit cell C illustrated in FIG. 4, the disclosure is not limited thereto, and as such, according to an embodiment, some of the bit cells C′ in the bit cell array 500 may be same as the bit cell C illustrated in FIG. 4, while other of the bit cells C′ the bit cell array 500 may be different from the bit cell C illustrated in FIG. 4,

Referring to FIG. 6, according to an embodiment, each of the bit cells C′ may include a plurality of nonvolatile memories M′ connected in parallel with each other, a first switch SW1 connected between one end of the plurality of nonvolatile memories M′ and one of the plurality of source lines (e.g., SL3), and the second switches SW2 arranged between one end of the bit lines (e.g., BL3) and the other end of each of the nonvolatile memories M′.

For convenience of explanation, the number of nonvolatile memories M′ is illustrated as three in FIG. 6, but the disclosure is not limited thereto. For example, the number of nonvolatile memories M′ may be at least two, and the number of nonvolatile memories M′ may increase or decrease in proportion to the data writing accuracy required in the neural network apparatus. The number of second switches SW2 may be increased or decreased to match the number of nonvolatile memories M′.

The plurality of nonvolatile memories M′ may include a first nonvolatile memory R₃₃₁, a second nonvolatile memory R₃₃₂, and a third nonvolatile memory R₃₃₃ that are connected in parallel with each other.

The nonvolatile memories M′ according to an embodiment may be one of PRAM, RRAM, MRAM, FeRAM, eFlash, and FeFET.

The nonvolatile memories M′ according to an embodiment may have substantially the same conductivity (S/cm). For example, the first nonvolatile memory R₃₃₁, the second nonvolatile memory R₃₃₂, and the third nonvolatile memory R₃₃₃ may all include the same type of resistive element (e.g., PRAM).

The first switch SW1 may control the current supply to the nonvolatile memory M′ by being turned-on or turned-off according to a voltage of the word line (e.g., WL3).

The second switches SW2 may include a 2-1 switch S11 arranged between the bit line (e.g., BL3) and the first nonvolatile memory R₃₃₁, a 2-2 switch S21 arranged between the bit line (e.g., BL3) and the second nonvolatile memory R₃₃₂, and a 2-3 switch S31 arranged between the bit line (e.g., BL3) and the third nonvolatile memory R₃₃₃.

The second switches SW2 may be sequentially turned-on to sequentially provide a true value provided through the bit lines (e.g., BL3) to each of the nonvolatile memories M′. For example, when writing data, first, the 2-1 switch S11 is turned-on, and the 2-2 switch S21 and the 2-3 switch S31 are turned-off, the bit lines (e.g., BL3) and the first nonvolatile memory R₃₃₁ are electrically connected, and thus, a true value provided through the bit lines (e.g., BL3) may be written to the first nonvolatile memory R₃₃₁. Then, when the 2-2 switch S21 is turned-on and the 2-1 switch S11 and the 2-3 switch S31 are turned-off, the bit lines (e.g., BL3) and the second nonvolatile memory R₃₃₂ are electrically connected, and thus, the true value provided through the bit lines (e.g., BL3) may be written to the second nonvolatile memory R₃₃₂. Then, when the 2-3 switch S31 is turned-on and the 2-1 switch S11 and the 2-2 switch S21 are turned-off, the bit lines (e.g., BL3) and the third nonvolatile memory R₃₃₃ are electrically connected, and thus, the true value provided through the bit lines (e.g., BL3) may be written to the third nonvolatile memory R₃₃₃.

According to an embodiment, the first switch SW1 and the second switches SW2 may be MOS transistors or bipolar transistors.

Referring to FIGS. 5 to 7, the bit cells C′ arranged in the first direction (Y direction) may be connected in parallel to form one column circuit 520. For example, the column circuit 520 indicated by the dashed line (in FIG. 5) may be configured by connecting n bit cells C′ arranged in the first direction (Y direction) to the first source line SL1 and the first bit line BL1 in parallel.

In an example case in which a neural network operation is performed, the bit cells C′ have a plurality of nonvolatile memories M′ corresponding to the weights, and when a voltage corresponding to input activation is applied to each of the plurality of word lines WL1, WL2, . . . , WLn, the first switch SW1 is turned on or off to control the current supply to the nonvolatile memory M′. In an example case in which the second switches SW1 are sequentially turned-on, current according to Ohm's law may be output through each bit cell C′. Because the currents output from the bit cells arranged along one column circuit are combined, the sum currents I₁, I₂, I₃, . . . , Iₘ may be output along multiple bit lines BL1, BL2, . . . , BLm. The sum currents I₁, I₂, I₃, . . . , Iₘ may correspond to the results of a neural network operation (or, an analog MAC) performed in an analog manner.

The neural network apparatus may include a current-to-voltage converter 710, a voltage accumulator 720 and an analog-to-digital converter (ADC) 730. The current-to-voltage converter 710 is arranged between bit lines and an analog-to-digital converter (ADC) 730. The voltage accumulator 720 calculates an accumulated voltage value by adding up the voltage values output from the current-to-voltage converter 710. The analog-to-digital converter 730 converts the results of the analog MAC operation output (or, an accumulated voltage value output from the voltage accumulator 720) from the bit lines into a digital signal.

The current-to-voltage converter 710 may include an operational amplifier including a non-inverting input terminal IE2 connected to a ground power supply, an inverting input terminal IE1 connected to bit lines (e.g., BL1), and an output terminal OE connected to a voltage accumulator 720. The operational amplifier may include third switches SW3 connected in parallel between the inverting input terminal IE1 and the output terminal OE.

The third switches SW3 may include a 3-1 switch S12 that is turned-on or turned-off simultaneously with the 2-1 switch S11, a 3-2 switch S22 that is turned-on or turned-off simultaneously with the 2-2 switch S21, and a 3-3 switch S32 that is turned-on or turned-off simultaneously with the 2-3 switch S31. That is, the number of second switches SW2 may be the same as the number of third switches SW3.

The operational amplifier may include variable resistors VR connected in series with third switches SW3 between the inverting input terminal IE1 and the output terminal OE. The variable resistors VR may include a first variable resistor R₁ connected in series with the 3-1 switch S12, a second variable resistor R₂ connected in series with the 3-2 switch S22, and a third variable resistor R₃ connected in series with the 3-3 switch S32.

The variable resistors VR correspond to a configuration for scale conversion corresponding to the conductance (or, conductivity) of each of the nonvolatile memories M′ in the bit cell C′. In an example case in which a ratio between the conductance (or conductivity) of the first nonvolatile memory R₃₃₁, the conductance (or conductivity) of the second nonvolatile memory R₃₃₂, and the conductance (or conductivity) of the third nonvolatile memory R₃₃₃ is 1:1:1, the resistance value of the first variable resistor R1: the resistance value of the second variable resistor R2: the third variable resistor R3=1:0.1:0.01.

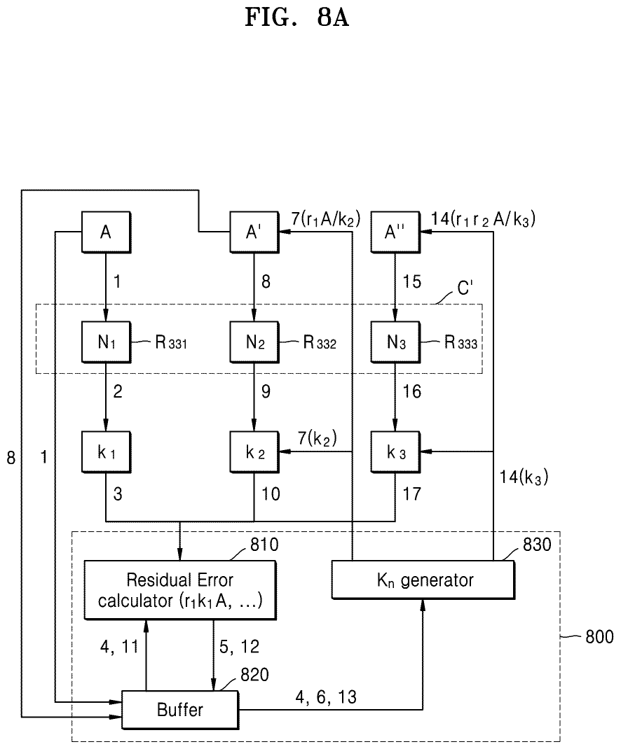

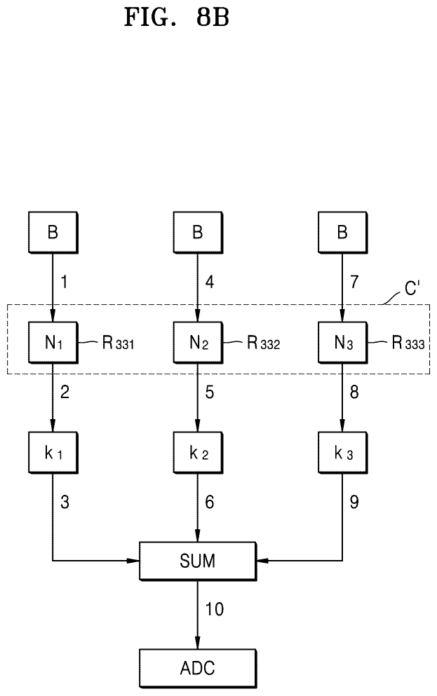

FIG. 8A is a flowchart for explaining a writing circuit of a neural network apparatus, and FIG. 8B is a flowchart for explaining the operation (or reading) circuit of the neural network apparatus. According to an embodiment, the numbers 1 to 17 written next to the arrow guidance line of FIG. 8A and the numbers 1 to 9 written next to the arrow guidance line of FIG. 8B indicate the order of operations.

Referring to FIGS. 5 to 8A, according to an embodiment a neural network apparatus may further include a controller 800 including a residual error calculator 810 that calculates an error rate by using a difference value between a true value (e.g., A, A′, A″) provided to each of nonvolatile memories (e.g., R₃₃₁, R₃₃₂, and R₃₃₃) and an actual value (e.g., N₁, N₂, and N₃) recorded in each of the nonvolatile memories (e.g., R₃₃₁, R₃₃₂, and R₃₃₃), a buffer 820 that stores true values (e.g., A, A′, A″) and error rates (e.g., r₁, r₂, and r₃), and a scale constant generator 830 that calculates a scale constant Kₙ of each of the nonvolatile memories (e.g., R₃₃₁, R₃₃₂, and R₃₃₃) based on the true values (e.g., A, A′, A″) and the error rates (e.g., r₁, r₂, and r₃).

The scale constant Kₙ may be obtained by the following equation (2).

$${k}_{n} = \frac{{\sum }_{j}^{m} ( {\prod }_{i}^{n - 1} {r}_{ij} ) {A}_{j}}{{\sum }_{j}^{m} {A}_{j}} \qquad ( 2 )$$

Here, Kₙ is the scale constant of the nth nonvolatile memory M′ in the bit cell C′, m(j^{th}) is the number of bit cells C′ in the column, n(i^{th}) is the number of nonvolatile memories M′ in the bit cell C′, rᵢⱼ is the error rate (0~1) of the i^{th} nonvolatile memory M′ in the j^{th} bit cell C′, and Aⱼ is the input true value in the j^{th} bit cell C′.

The resistance value of each of the variable resistors VR may be proportional to the scale constant Kₙ. For example, the resistance value of the first variable resistor R₁ may be proportional to the first scale constant k₁, the resistance value of the second variable resistor R₂ may be proportional to the second scale constant K₂, and the resistance value of the third variable resistor R₃ may be proportional to the third scale constant K₃.

During a data write operation, the first true value A may be first written to the first nonvolatile memory R₃₃₁ in the bit cell C′. According to an embodiment, while the first true value A is written to the first nonvolatile memory R₃₃₁ in the bit cell C′, the 2-1 switch S11 of the second switch SW2 and the 3-1 switch S12 of the third switch SW3 are in a turned-on state, and the 2-2 switch S21, the 2-3 switch S31, the 3-2 switch S22, and the 3-3 switch S32 are in a turned-off state. In addition, the first scale constant k₁ may be 1 as a preset value.

The first true value A may be simultaneously provided to the bit cell C′ and the buffer 820. The residual error calculator 810 may calculate the first error rate r₁ by using the difference between the first true value A provided from the buffer 820 and an actual value N₁ provided from the first nonvolatile memory R₃₃₁. For convenience of explanation, assuming that each of the nonvolatile memories (e.g., R₃₃₁, R₃₃₂, and R₃₃₃) has a write accuracy of 90% with respect to the true value (A, A′, and A″), the actual value N₁ recorded in the first nonvolatile memory R₃₃₁ may be 0.9 A. In this case, the first error rate r₁ is 0.1.

According to an embodiment, the scale constant generator 830 may use equation (2) to calculate the second scale constant k₂. As a result, the second scale constant k₂ may be 0.1 because it corresponds to the product of the first scale constant k₁ and the first error rate r₁. The second true value A′ provided to the second nonvolatile memory R₃₃₂ is the scale-converted first true value A, which is obtained by multiplying the first error rate r₁ by the first true value A.

According to an embodiment, in the process of calculating the second true value A′, the reason for dividing the value obtained by multiplying the first true value A by the first error rate r₁ by the second scale constant K₂ may be a scaling process to match the conductivity region of the second nonvolatile memory R₃₃₂. For example, assuming that the first true value A is 1 and the first error rate r₁ is 0.1, the residual error may be 0.1. However, in an example case in which the conductivity of the second nonvolatile memory R₃₃₁ has a region in which numbers of the order of 1 may be written (e.g., 1 to 10), 0.1 must be used as the actual value N₂, but considering the available conductivity region, it may be a small number to write in the second nonvolatile memory R₃₃₂. In this case, this problem may be solved by writing A, which is a value obtained by multiplying 10, the reciprocal of the second scale constant K₂ (e.g., 0.1), as the scaling value, to the second nonvolatile memory R₃₃₂.

The second true value A′ may be written to the second nonvolatile memory R₃₃₂ in the bit cell C′. As described above, because it is assumed that the second nonvolatile memory R₃₃₂ has a write accuracy of 90% compared to the second true value A′, the actual value N₂ written to the second nonvolatile memory R₃₃₂ may be 0.9 A. In this case, the second error rate r₂ is 0.1. According to an embodiment, while the second true value A′ is written to the second nonvolatile memory R₃₃₂ in the bit cell C′, the 2-2 switch S21 of the second switch SW2 and the 3-2 switch S22 of the third switch SW3 are turned-on, and the 2-1 switch S11, the 2-3 switch S31, the 3-1 switch S12, and the 3-3 switch S32 are turned-off.

The actual value N₂ may be scaled to a real-size number (e.g., 0.09 A) by being multiplied again by the second scale constant k₂ (e.g., 0.1) before being provided to the residual error calculator 810.

According to an embodiment, the scale constant generator 830 may calculate the third scale constant k₃ using the equation (2). As a result, the third scale constant k₃ may be 0.01 because the third scale constant k₃ corresponds to the product of the second scale constant k₂ and the second error rate r₂. The third true value A″ provided to the third nonvolatile memory R₃₃₃ is a scaled first true value A, which corresponds to a value obtained by multiplying the first true value A by the first error rate r₁ and the second error rate r₂ and dividing the value by the third scale constant k₃, and thus, the third true value A″ may be A.

According to an embodiment, in the process of calculating the third true value A″, the reason for dividing the value obtained by multiplying the first error rate r₁ and the second error rate r₂ by the third scale constant k₃ may be a scaling process to match the conductivity range of the third nonvolatile memory R₃₃₃. For example, assuming that the first true value A is 1, and the first error rate r₁ and the second error rate r₂ are both 0.1, the residual error may be 0.01. However, in an example case in which the conductivity of the third nonvolatile memory R₃₃₃ has a region where numbers of the order of 1 may be written (e.g., 1 to 10), 0.01 must be written as the actual value N₃, which may be a small number to write to the third nonvolatile memory R₃₃₃ considering the available conductivity region. In this case, this problem may be solved by writing A to the third nonvolatile memory R₃₃₃, wherein A is a value obtained by multiplying 100, which is the reciprocal of the third scale constant k₃ (e.g. 0.01), by a scaling value.

The third true value A″ may be written to the third nonvolatile memory R₃₃₃ in the bit cell C′. As described above, because it is assumed that the third nonvolatile memory R₃₃₃ has a write accuracy of 90% with respect to the third true value A″, the actual value N₃ written to the third nonvolatile memory R₃₃₃ may be 0.9 A. At this time, while the third true value A″ is written to the third nonvolatile memory R₃₃₃ in the bit cell C′, the 2-3 switch S31 of the second switch SW2 and the 3-3 switch S32 of the third switch SW3 are in a turned-on state, and the 2-1 switch S11, the 2-2 switch S21, the 3-1 switch S12, and the 3-2 switch S22 are in a turned-off state.

The actual value N₃ may be scaled to an actual size number (e.g., 0.009 A) by being multiplied again by the third scale constant k₃ (e.g., 0.01) before being provided to the residual error calculator 810.

As a result, for a 10% error value (=0.1 A) that occurred after writing in the first nonvolatile memory R₃₃₁, through writing to the second nonvolatile memory R₃₃₂ scaled ( 1/10), a 90% accurate value and a 10% error value (=0.01 A) for the residual value of 0.1 A are generated, securing a final accuracy of 0.9 A+0.09 A=0.99 A (99%), and thus, it possible to control analog errors below 1% by using only two nonvolatile memories R₃₃₁ and R₃₃₂. As described above, when using the three nonvolatile memories R₃₃₁, R₃₃₂, and R₃₃₃, an analog error control of less than 0.1% may be possible.

The data write accuracy of a bit cell may be obtained by the following equation (3).

$${A}_{n} = {\sum }_{k = 1}^{n} ( 1 - {r}_{k} ) {\prod }_{i = 0}^{k - 1} {r}_{i} A , where {r}_{0} = 1 \qquad ( 3 )$$

Here, An is the data write accuracy of a bit cell for the true value A of n nonvolatile memories M′, and rᵢ is the error rate (0 to 1) of the i^{th} nonvolatile memory M′.

The controller 800 according to an embodiment may maintain a turned-off state of a next second switch (e.g., S21) among the second switches SW2 illustrated in FIG. 6 when an error rate of a nonvolatile memory (e.g., R₃₃₁) connected to a turned-on second switch (e.g., S11) is less than a preset threshold value (e.g., 0.05). That is, in an example case in which the error rate of the first nonvolatile memory R₃₃₁ is less than 0.05, because 95% accuracy has already been secured, error correction using the second nonvolatile memory R₃₃₂ and the third nonvolatile memory R₃₃₃ may be unnecessary.

As described above, in an example case in which the error rates of the nonvolatile memories M′ in the bit cell C′ are the same, the data write accuracy of the bit cell may be simply obtained by the following equation (4).

$${A}_{n} = ( 1 - {r}^{n} ) \times A \qquad ( 4 )$$

Here, An is the data write accuracy of the bit cell for the true value A of n nonvolatile memories M′, and r is the error rate (0 to 1) of the nonvolatile memory M′.

Therefore, even in an example case in which the bit cell C′ includes (or uses) only two nonvolatile memories M′ having 80% write accuracy (error rate, r=0.2), the bit cell C′ may have 96% accuracy, and thus, it may be seen that it is a very effective method for improving data write accuracy.

A neural network apparatus (or, the structure of a bit cell C′) according to an embodiment may effectively increase precision even when the write performance of a unit nonvolatile memory (e.g., R₃₃₁, R₃₃₂, and R₃₃₃) is very low (for example, even when r=0.3 in equation (4), accuracy of up to 0.91 is guaranteed with only n=2), and further, with respect to PVT variation (e.g., variation in semiconductor characteristics caused by changing in process, voltage, and temperature) occurring in the production of an analog crossbar array, or performance variation between nonvolatile memories M′ (e.g., variation caused by device characteristics, non-uniformity of the manufacturing process, usage environment, etc.), the high cost required for additional circuits and algorithms specialized for each nonvolatile memory M′ may be reduced only by producing the bit cell C′ according to an embodiment.

Through the structure of the bit cell C′, it is expected to reduce the trade-off between accuracy and power consumption, which was raised as a problem of the related art method, and at the same time, power consumption and production cost may be reduced by using a single layer instead of using multiple analog crossbar layers for resolving residual errors.

Referring to FIGS. 5 to 8B, in an example case in which an operation (e.g., a read operation) is performed, if an input value B is first provided to the first nonvolatile memory R₃₃₁ in the bit cell C′, the actual value N₁, 0.9 A, previously stored in the first nonvolatile memory R₃₃₁ and the result of the multiplication operation, 0.9AB, may be recorded. According to an embodiment, the first scale constant k₁ may be 1 as a preset value.

According to an embodiment, in an example case in which the input value B is provided to the second nonvolatile memory R₃₃₂ in the bit cell C′, the actual value N₂, 0.9 A, previously stored in the second nonvolatile memory R₃₃₂ and the result of the product operation, 0.9AB, may be recorded. According to an embodiment, the second scale constant k₂ may be 0.1 as a value calculated in advance during the data write operation.

In an example in which the input value B is provided to the third nonvolatile memory R₃₃₃ in the bit cell C′, the actual value N₃, 0.9 A, stored in the third nonvolatile memory R₃₃₃ and the result of the multiplication operation, 0.9AB, may be recorded. According to an embodiment, the third scale constant k₃ may be 0.01 as a value calculated in advance during the data write operation.

Therefore, the output value of the bit cell C′ may be 0.999AB, which is the sum of the output value of the first nonvolatile memory R₃₃₁, the value obtained by multiplying the second scale constant k₂ by the second nonvolatile memory R₃₃₂ (e.g., 0.09AB), and the value obtained by multiplying the second scale constant k₂ by the third nonvolatile memory R₃₃₃ (e.g., 0.009AB). The analog sum value may be provided to an analog-to-digital converter.

Hereinafter, other embodiments will be described. In the embodiments below, descriptions of the same configurations as the embodiments already described will be omitted or simplified, and differences will be mainly described.

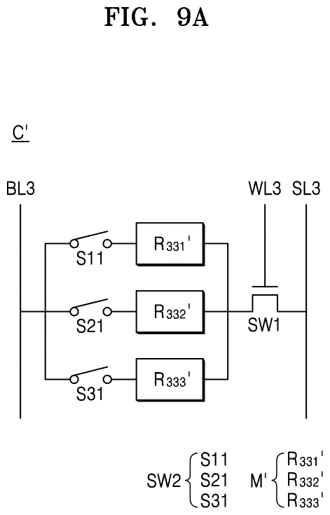

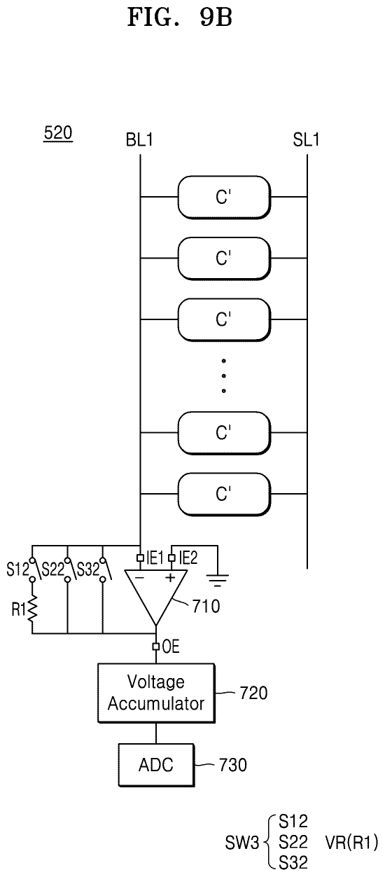

FIG. 9A is a modified embodiment of the bit cell illustrated in FIG. 6. FIG. 9B is a modified embodiment of the column circuit illustrated in FIG. 7.

The only difference is that the plurality of nonvolatile memories M′ in the bit cell C′ illustrated in FIG. 9A include different types of elements, and the plurality of nonvolatile memories M′ in the bit cell C′ illustrated in FIG. 6 include the same type of elements, but the remaining configurations are substantially the same. In addition, the current-to-voltage converter 710 illustrated in FIG. 9B differs from the current-to-voltage converter 710 illustrated in FIG. 7 in that the current-to-voltage converter 710 includes only a first variable resistor R₁ connected in series with the 3-1 switch S12, a second variable resistor R₂ connected in series with the 3-2 switch S22, and a third variable resistor R₃ connected in series with the 3-3 switch S32, in that the variable resistor VR is substantially the same as the remaining configurations.

Referring to FIGS. 9A and 9B, nonvolatile memories M′ in a unit bit cell C′ according to an embodiment may include elements having different conductivities.

The conductivity range of PRAM is in a range from about 10⁻⁶ S/cm to 10⁻² S/cm, the conductivity range of MRAM is in a range from about 10⁻⁸ S/cm to 10⁻⁴ S/cm, the conductivity range of RRAM is in a range from about 10⁻¹⁰ S/cm to 10⁻⁶ S/cm, and the conductivity range of Flash Memory is in a range from about 10⁻⁴ S/cm to 10⁻² S/cm.

According to an embodiment, in an example case in which the number of nonvolatile memories M′ included in each bit cell C′ is three, the first nonvolatile memory R₃₃₁ is PRAM, the second nonvolatile memory R₃₃₂ is MRAM, the third nonvolatile memory R₃₃₃ is RRAM, and the conductivity of the PRAM may be about 10⁻⁶ S/cm, the conductivity of the MRAM may be about 10⁻⁷ S/cm, and the conductivity of the RRAM may be about 10⁻⁸ S/cm.

In this way, in an example case in which the conductivities between the first nonvolatile memory R₃₃₁, the second nonvolatile memory R₃₃₂, and the third nonvolatile memory R₃₃₃ differ by a certain ratio (e.g., 10⁻¹), the scale conversion has already been performed, and accordingly, the feedback resistors of the current-to-voltage converter 710 required for the scale conversion may be omitted. Therefore, in an example case in which the bit cell C′ is configured of a combination of a plurality of nonvolatile memories having different conductivities from each other, the effect of simplifying the peripheral circuit may be expected.

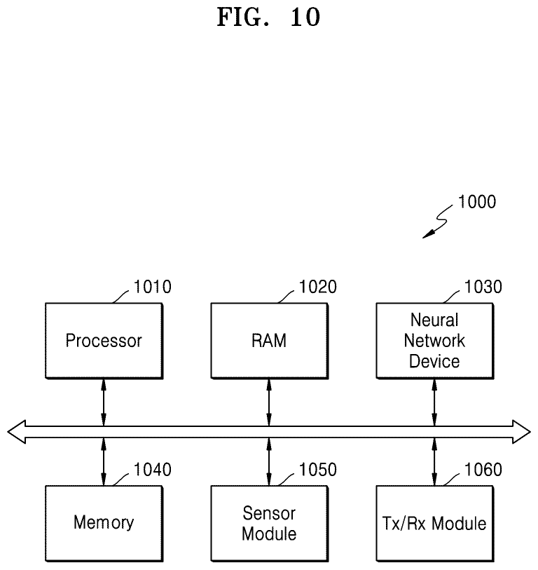

FIG. 10 is a block diagram showing the configuration of an electronic system 1000 according to an embodiment.

Referring to FIG. 10, the electronic system 1000 analyzes input data in real time based on a neural network to extract valid information, and may determine a situation based on the extracted information or control the configurations of an electronic device on which the electronic system 1000 is mounted. For example, the electronic system 1000 may be applied to robot devices such as drones, Advanced Drivers Assistance Systems (ADAS), smart TVs, smartphones, medical devices, mobile devices, image display devices, measuring devices, IoT devices, etc., and may also be mounted on at least one of various types of electronic devices.

The electronic system 1000 may include a processor 1010, RAM 1020, a neural network device 1030, a memory 1040, a sensor module 1050, and a communication module 1060. The electronic system 1000 may further include an input/output module, a security module, a power control device, etc. Some of the hardware components of the electronic system 1000 may be mounted on at least one semiconductor chip.

The processor 1010 controls the overall operation of the electronic system 1000. The processor 1010 may include a single processor core (Single-core) or multiple processor cores (Multi-Core). The processor 1010 may process or execute programs and/or data stored in the memory 1040. In one or more embodiments, the processor 1010 may control the function of the neural network device 1030 by executing programs stored in the memory 1040. The processor 1010 may be implemented as a CPU, a GPU, an AP, etc.

The RAM 1020 may temporarily store programs, data, or instructions. For example, programs and/or data stored in the memory 1040 may be temporarily stored in the RAM 1020 according to the control or boot code of the processor 1010. The RAM 1020 may be implemented as a memory such as Dynamic RAM (DRAM) or Static RAM (SRAM).

The neural network device 1030 may perform a neural network operation based on received input data and generate an information signal based on the performance result. The neural network may include, but the disclosure is not limited to, CNN, RNN, FNN, Deep Belief Networks, Restricted Boltzmann Machines, etc. The neural network device 1030 may be a hardware accelerator dedicated to the neural network itself or a device including the same. The neural network device 1030 may perform operations of reading or writing as well as operations of the neural network.

An information signal may include one of various types of recognition signals, such as a voice recognition signal, an object recognition signal, an image recognition signal, a biometric information recognition signal, etc. For example, the neural network device 1030 may receive frame data included in a video stream as input data, and generate a recognition signal for an object included in an image represented by the frame data from the frame data. However, the neural network device 1030 is not limited thereto, and depending on the type or function of the electronic device equipped with the electronic system 1000, the neural network device 1030 may receive various types of input data and generate a recognition signal according to the input data.

The memory 1040 is a storage location for storing data, and may store an Operating System (OS), various programs, and various data. In an embodiment, the memory 1040 may store intermediate results generated during the operation performing process of the neural network device 1030.

The memory 1040 may be DRAM, but the disclosure is not limited thereto. The memory 1040 may include at least one of volatile memory or nonvolatile memory. The nonvolatile memory includes ROM, PROM, EPROM, EEPROM, flash memory, PRAM, MRAM, RRAM, FRAM, etc. The volatile memory includes DRAM, SRAM, SDRAM, etc. In an embodiment, the memory 1040 may include at least one of hard disk drive (HDD), solid state drive (SSD), CF, SD, Micro-SD, Mini-SD, xD, or Memory Stick.

The sensor module 1050 may collect information about the surroundings of an electronic device in which an electronic system 1000 is mounted. The sensor module 1050 may sense or receive signals (e.g., image signals, voice signals, magnetic signals, bio-signals, touch signals, etc.) from the outside of the electronic device, and convert the sensed or received signals into data. To this end, the sensor module 1050 may include at least one of various types of sensing devices, such as a microphone, an imaging device, an image sensor, a light detection and ranging (LiDAR) sensor, an ultrasonic sensor, an infrared sensor, a bio-sensor, and a touch sensor.

The sensor module 1050 may provide the converted data as input data to the neural network device 1030. For example, the sensor module 1050 may include an image sensor, generate a video stream by capturing an external environment of the electronic device, and sequentially provide continuous data frames of the video stream as input data to the neural network device 1030. However, it is not limited thereto, and the sensor module 1050 may provide various types of data to the neural network device 1030.

The communication module 1060 may be equipped with various wired or wireless interfaces capable of communicating with external devices. For example, the communication module 1060 may include a communication interface that may be connected to a wired local area network (LAN), a wireless local area network (WLAN) such as Wireless Fidelity (Wi-fi), a wireless personal area network (WPAN) such as Bluetooth, a wireless universal serial bus (USB), Zigbee, near field communication (NFC), radio-frequency identification (RFID), power line communication (PLC), or a mobile cellular network such as 3rd Generation (3G), 4th Generation (4G), or Long Term Evolution (LTE).

According to the neural network apparatus according to embodiments, it is expected that the residual errors during data writing may be reduced without excessive increase in power consumption and production cost through a simple change in the bit cell structure.

The effects of the embodiments are not limited to the effects described above, and effects not mentioned may be clearly understood by those of ordinary skill in the art to which the embodiments belong from the specification and the accompanying drawings.

While the embodiments have been described in detail, the scope of the disclosure is not limited thereto, and various modifications and improvements made by those skilled in the art using the basic concept of the disclosure defined in the following claims also fall within the scope of the present invention.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A neural network apparatus comprising:
a plurality of bit lines extending in a first direction;
a plurality of word lines extending in a second direction intersecting with the first direction;
a plurality of source lines extending in parallel with the plurality of bit lines in the first direction; and
a plurality of bit cells, each of the plurality of bit cells arranged in a region where a respective one of the plurality of bit lines and a respective one of the plurality of word lines intersect,
wherein each of the plurality of bit cells comprises:
a plurality of nonvolatile memories;
a first switch connected between a first end of each of the plurality of nonvolatile memories and one of the plurality of source lines; and
a plurality of second switches, each of the plurality of second switches connected to one of the plurality of bit lines and a second end of a respective one of the plurality of nonvolatile memories.

2. The neural network apparatus of claim 1, further comprising an analog-to-digital converter configured to convert results of analog multiply-accumulate (MAC) operations output from the plurality of bit lines into digital signals.

3. The neural network apparatus of claim 2, further comprising a current-to-voltage converter and a voltage accumulator arranged between the plurality of bit lines and the analog-to-digital converter.

4. The neural network apparatus of claim 3, wherein the current-to-voltage converter comprises an operational amplifier comprising a non-inverting input terminal connected to a ground power supply, an inverting input terminal connected to the plurality of bit lines, and an output terminal connected to a voltage accumulator, wherein the operational amplifier comprises a plurality of third switches connected in parallel with each other between the inverting input terminal and the output terminal.

5. The neural network apparatus of claim 4, wherein the operational amplifier comprises variable resistors connected in series with the plurality of third switches between the inverting input terminal and the output terminal.

6. The neural network apparatus of claim 5, further comprising:
a controller comprising a residual error calculator configured to calculate an error rate using a difference value between a true value provided to each of the plurality of nonvolatile memories and an actual value recorded in each of the plurality of nonvolatile memories;
a buffer configured to store the true value and the error rate; and
a scale constant generator configured to calculate a scale constant of each of the plurality of nonvolatile memories based on the true value and the error rate.

7. The neural network apparatus of claim 6, wherein the scale constant is obtained by following Equation:
$${K}_{n} = \frac{{\sum }_{j}^{m} ( {\prod }_{i}^{n - 1} {r}_{ij} ) {A}_{j}}{{\sum }_{j}^{m} {A}_{j}}$$
wherein kₙ is the scale constant of the n^{th} nonvolatile memory in the bit cell, m(j^{th}) is a number of bit cells in a column, n(i^{th}) is a number of nonvolatile memories in the bit cell, rᵢⱼ is the error rate (0~1) of the i^{th} nonvolatile memory in the j^{th} bit cell, and Aⱼ is an input true value in the j^{th} bit cell.

8. The neural network apparatus of claim 6, wherein, in case of writing data, the true value provided through the plurality of bit lines is sequentially written to each of the plurality of nonvolatile memories by sequentially turning-on the plurality of second switches.

9. The neural network apparatus of claim 8, wherein data writing accuracy of a bit cell, among the plurality of bit cells, is obtained by following Equation:
$${A}_{n} = {\sum }_{k = 1}^{n} ( 1 - {r}_{k} ) {\prod }_{i = 0}^{k - 1} {r}_{i} A , where {r}_{0} = 1$$
wherein Aₙ is the data write accuracy of the bit cell for the true value A of n nonvolatile memories, and rᵢ is the error rate of the i^{th} nonvolatile memory (0 to 1).

10. The neural network apparatus of claim 8, wherein the controller is configured to maintain a turn-off state of a second second switch among the plurality of second switches in a case in which the error rate of a first nonvolatile memory, among the plurality of nonvolatile memories, connected to a first second switch turned-on among the plurality of second switches is less than a threshold value.

11. The neural network apparatus of claim 6, wherein a resistance value of each variable resistor is proportional to the scale constant.

12. The neural network apparatus of claim 4, wherein the plurality of nonvolatile memories have substantially the same conductivity.

13. The neural network apparatus of claim 4, wherein the plurality of nonvolatile memories comprise one of phase change random access memory (PRAM), resistive random access memory (RRAM), magnetic random access memory (MRAM), ferroelectric random access memory (FeRAM), eFlash, or FeFET.

14. The neural network apparatus of claim 4, wherein a number of the plurality of second switches is same as a number of the plurality of third switches.

15. The neural network apparatus of claim 3, wherein the plurality of nonvolatile memories have different conductivities.

16. The neural network apparatus of claim 15, wherein, a number of the plurality of nonvolatile memories in each of the bit cells is three,
wherein the plurality of nonvolatile memories comprises a first nonvolatile memory, a second nonvolatile memory and a third nonvolatile memory, and
wherein the first nonvolatile memory is phase change random access Memory (PRAM), the second nonvolatile memory is magnetic random access memory (MRAM), and the third nonvolatile memory is resistive random access memory (RRAM), wherein the conductivity of the PRAM is about 10⁻⁶ S/cm, the conductivity of the MRAM is about 10⁻⁷ S/cm, and the conductivity of the RRAM is about 10-8 S/cm.

17. The neural network apparatus of claim 1, wherein, in a case in which a neural network operation is performed, the plurality of bit cells connected to one of the plurality of bit lines output a sum current to the bit line based on a voltage applied to the plurality of word lines.

18. The neural network apparatus of claim 1, wherein the first switch and the plurality of second switches comprise MOS transistors or bipolar transistors.

19. An electronic system comprising:
the neural network apparatus according to claim 1;
a memory; and
a processor configured to control one or more operations of the neural network apparatus by executing programs stored in the memory,
wherein the neural network apparatus is configured to perform a neural network operation based on input data received from the processor and generate an information signal corresponding to the input data based on a result of the neural network operation.

20. The electronic system of claim 19, wherein, in a case in which the neural network operation is performed, the plurality of bit cells connected to one of the plurality of bit lines output a sum current to the one of the plurality of bit lines based on a voltage applied to the plurality of word lines.
